(19) United States
(12) Patent Application Publication
(10) Pub. No.: US 2024/0194707 A1
(43) Pub. Date: Jun. 13, 2024

(54) ENHANCED AREA GETTER ARCHITECTURE FOR WAFER-LEVEL VACUUM PACKAGED UNCOOLED FOCAL PLANE ARRAY

(71) Applicant: DRS Network & Imaging Systems, LLC, Melbourne, FL (US)

(72) Inventors: Thomas Schimert, Midlothian, TX (US); Kuni Shimizu, Carrollton, TX (US)

(73) Assignee: DRS Network & Imaging Systems, LLC, Melbourne, FL (US)

(21) Appl. No.: 18/530,100

(22) Filed: Dec. 5, 2023

Related U.S. Application Data
(60) Provisional application No. 63/430,953, filed on Dec. 7, 2022.

(51) Int. Cl. H01L 27/146; H01L 23/26

(52) U.S. Cl. CPC H01L 27/14618; H01L 23/26; H01L 27/14683

(57) ABSTRACT

Methods and systems utilizing an enhanced area getter architecture for wafer-level vacuum packaged, uncooled focal plane array (FPA) assembly are disclosed. The FPA assembly includes a device die having a first device surface, an infrared detector array disposed on the first device surface, an infrared reference pixel disposed on the first device surface, and a window die bonded to the device die. The window die includes a recess and comprises a first die surface that overlies the infrared detector array, a second die surface that overlies the infrared reference pixel, and a die wall surface joining the first die surface and the second die surface. The die wall surface forms a perimeter of the recess and a getter material is disposed on at least one of the die wall surface or the first die surface.

### CROSS REFERENCE TO RELATED APPLICATIONS

This application claims priority to U.S. Provisional Patent Application No. 63/430,953, entitled “Enhanced Area Getter Architecture for Wafer-level Vacuum Packaged Uncooled Focal Plane Array,” filed on Dec. 7, 2022, the disclosure of which is hereby incorporated by reference in its entirety for all purposes.

The following regular U.S. patent applications (including this one) are being filed concurrently, and the entire disclosure of the other application is hereby incorporated by reference into this application for all purposes:
U.S. patent application Ser. No. ______, filed on Dec. 5, 2023, entitled “ENHANCED AREA GETTER ARCHITECTURE FOR WAFER-LEVEL VACUUM PACKAGED UNCOOLED FOCAL PLANE ARRAY;” and
U.S. patent application Ser. No. ______, filed on Dec. 5, 2023, entitled “METHODS AND SYSTEMS FOR FABRICATION OF INFRARED TRANSPARENT WINDOW WAFER WITH INTEGRATED ANTI-REFLECTION GRATING STRUCTURES.”

### BACKGROUND OF THE INVENTION

As photodetector technology continues to develop, new designs can provide vastly improved resolution as compared to technology of the past. Resolution for photodetectors is at least partially determined by the number of pixels in the detector array. Typically, the more pixels in the detector array, the more detail that can be provided during imaging operations. Improved technologies have enabled manufacturing operations to produce pixels of much smaller size in order to maintain the overall form factors of the detector array, while incorporating more pixels to provide the improved resolution.

Despite the progress made in detector arrays, there is a need in the art for improved methods and systems related to detector arrays.

### SUMMARY OF THE INVENTION

In accordance with various aspects of the present disclosure, embodiments of the present disclosure relate to methods and systems with an enhanced area getter architecture for wafer-level vacuum packaged, uncooled focal plane arrays.

According to an embodiment of the present invention, a focal plane array (FPA) assembly is provided. The FPA assembly includes a device die having a first device surface, an infrared detector array disposed on the first device surface, and an infrared reference pixel array disposed on the first device surface and a window die bonded to the device die. The window die includes a recess and comprises a first die surface that overlies the infrared detector array, a second die surface that overlies the infrared reference pixel array, and a die wall surface joining the first die surface and the second die surface. The die wall surface forms a perimeter of the recess. The FPA assembly further includes a getter material disposed on at least one of the die wall surface or the first die surface.

In some embodiments, the recess extends into the window die along a first direction and the first die surface overlaps the infrared detector array in a plane orthogonal to the first direction. In various embodiments, the getter material is disposed on a portion of the second die surface. In some embodiments, the second die surface overlaps the infrared reference pixel array in the plane orthogonal to the first direction. In various embodiments, the perimeter of the recess is defined by four die wall surfaces and the getter material is disposed on the four die wall surfaces. In some embodiments, the FPA assembly further includes a seal ring disposed between the device die and the window die and encircling the recess. In various embodiments, the window die, the device die, and the seal ring form a hermetic cavity overlapping the infrared detector array. In some embodiments, the seal ring includes solder ring metallization and solder joints. In various embodiments, the infrared reference pixel array is disposed outside of the perimeter of the recess. In some embodiments, the getter material includes titanium. In some embodiments, the getter material is non-optically transmissive. In various embodiments, the getter material forms an optical blocking structure for the infrared reference pixel array. In some embodiments, pixel elements of the infrared reference pixel array are identical in configuration to pixel elements of the infrared detector array. In various embodiments, a pixel element of the infrared detector array includes a microbolometer detector pixel element.

According to another embodiment of the present invention, a method of fabricating a focal plane array (FPA) assembly is provided. The method includes providing a handle wafer having a bonding side and a planar side opposing the bonding side, providing a silicon on insulator wafer having a first side and a second side opposite the first side, and providing a device wafer having a plurality of solder joints. The method also includes bonding the first side of the silicon on insulator wafer to the bonding side of the handle wafer, forming a plurality of seal ring metallizations on the second side of the silicon on insulator wafer, and etching a recess into the second side of the silicon on insulator wafer to expose a portion of the bonding side of the handle wafer and forming a plurality of recess walls. The method further includes forming a first anti-reflection coating on a first portion of the planar side of the handle wafer, forming a second anti-reflection coating on a second portion of the bonding side of the handle wafer, depositing getter material on a third portion of the bonding side of the handle wafer, on the plurality of recess walls and on a fourth portion of the second side of the silicon on insulator wafer, and bonding the device wafer to the second side of the silicon on insulator wafer.

In some embodiments, the etching the recess into the second side of the silicon on insulator wafer is performed by dry etching followed by wet etching. In various embodiments, the device wafer comprises an infrared detector pixel array and an infrared reference pixel. In some embodiments, the infrared reference pixel is identical in configuration to a pixel element of the infrared detector pixel array. In some embodiments, depositing getter material is performed using a shadow mask. In various embodiments, the first portion of the bonding side of the handle wafer is disposed inside the plurality of recess walls. In some embodiments, the fourth portion of the second side of the silicon on insulator wafer is disposed outside the plurality of recess walls. In various embodiments, bonding the device wafer to the silicon on insulator wafer is performed by attaching the plurality of solder joints to the plurality of seal ring metallizations on the second side of the silicon on insulator wafer. In some embodiments, depositing getter material is performed after forming the first anti-reflection coating.

Numerous benefits are achieved by way of the present disclosure over conventional techniques. For example, embodiments of the present disclosure provide methods and systems for enhanced area getter architectures suitable for use in a wafer-level vacuum packaged, uncooled focal plane array (FPA). Embodiments enable use of a cavity formed within a window die in the FPA assembly to increase the surfaces that getter material can be formed on, thereby increasing getter sorption capacity in the cavity. In some embodiments, getter material is formed on the surface of the window die where a recess has not been etched, on the surface of the handle die in the recess region, and on the sidewall surface of the recess. The getter material area is increased by adding surface area of the sidewalls for getter deposition material, thereby increasing getter sorption capacity in the cavity. In various embodiments, the recess can be made deeper or shallower by adjusting a thickness of the window die. Optical aperture permitting, the recess depth can be increased, thereby increasing available getter area. Furthermore, embodiments of the disclosure enable the use of the enhanced area getter architecture to serve as a blocking structure for optically blind reference pixels. These and other embodiments of the disclosure, along with many of its advantages and features, are described in more detail in conjunction with the text below and attached figures.

### BRIEF DESCRIPTION OF THE DRAWINGS

Aspects of the present disclosure will now be described more fully hereinafter with reference to the accompanying drawings, which are intended to be read in conjunction with both this summary, the detailed description and any preferred and/or particular embodiments specifically discussed or otherwise disclosed. The various aspects may, however, be embodied in many different forms and should not be construed as limited to the embodiments as set forth herein; rather, these embodiments are provided by way of illustration only and so that this disclosure will be thorough and complete and will fully convey the full scope to those skilled in the art.

FIGS. 1A-1C illustrate a wafer-level vacuum packaging process for uncooled, bolometer-based, focal plane arrays according to embodiments of the disclosure.

FIG. 2 is a cross-sectional view of a focal plane array assembly according to an embodiment of the disclosure.

FIG. 3A shows a plan view of a device die with an infrared detector array and an infrared reference pixel array according to an embodiment of the disclosure.

FIG. 3B shows a plan view of a window die according to an embodiment of the disclosure.

FIG. 3C shows a plan view of the bonded device die and window die of FIGS. 3A and 3B, respectively, according to an embodiment of the disclosure.

FIGS. 4A-B show plan views of a shadow mask used for deposition of getter material onto the focal plane array assembly of FIG. 2 according to an embodiment of the disclosure.

FIGS. 5A-5G are cross section views illustrating a method of fabricating a focal plane array assembly according to an embodiment of the disclosure.

FIG. 6 illustrates a simplified flowchart illustrating a method of fabricating a focal plane array assembly according to an embodiment of the disclosure.

### DETAILED DESCRIPTION OF SPECIFIC EMBODIMENTS

The described embodiments relate generally to focal plane array (FPA) devices. More particularly, embodiments of the present disclosure provide methods and systems utilizing an enhanced area getter architecture for wafer-level vacuum packaged, uncooled FPA structures.

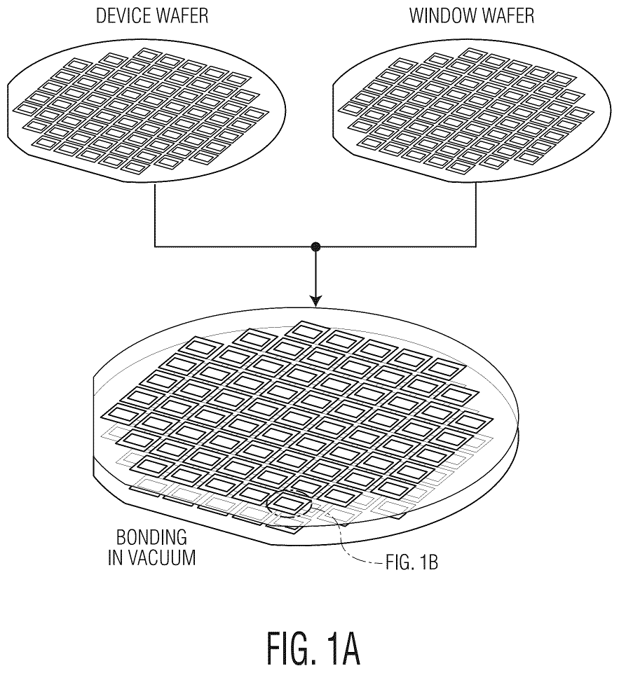

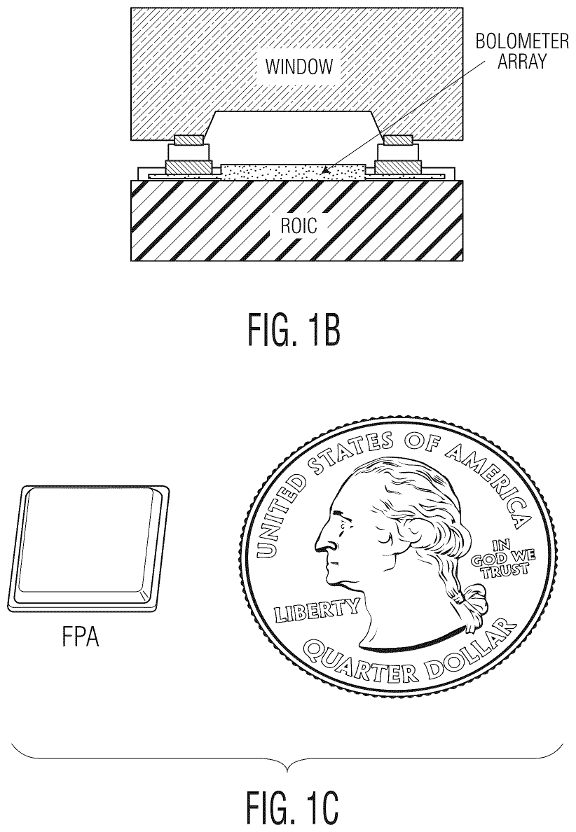

FIGS. 1A-1C illustrate a wafer-level vacuum packaging (WLVP) process for uncooled, bolometer-based, focal plane arrays (FPAs) according to embodiments of the disclosure. In the illustrated embodiment, a solder ring is placed around each die on the FPA wafer with a corresponding seal ring on the mating window wafer. The FPA wafer and window wafer can be aligned and bonded in a vacuum environment. After wafer bonding, slots are sawed in the window wafer to gain access to probe pads on the FPA wafer, thereby enabling post-bond, wafer-scale radiometric testing of vacuum packaged FPAs. Wafer-level vacuum packaging can provide a relatively low size, low weight, and low cost solution for packaging uncooled FPAs.

Modern bolometer-based uncooled infrared (IR) imaging FPAs may thermally isolate the bolometer pixel from the environment to maximize a temperature change of the bolometer pixel induced by infrared scene flux incident on the pixel. A temperature-dependent resistive transducer can detect the scene-induced temperature change through a change in resistance. The temperature-dependent resistive transducer can be made from, but not limited to, vanadium oxide (VOx) or amorphous silicon (a-Si). An array of bolometer pixels addressed by a readout integrated circuit (ROIC) chip allows the bolometer-based, uncooled infrared imaging FPA to image the scene. Thermal isolation of the bolometer pixel can be achieved using relatively long, low thermal conductivity legs that electrically connect the bolometer transducer to an underlying ROIC. In order to achieve relatively high sensitivity, the array of bolometer pixels can be vacuum packaged to reduce or eliminate thermal conductance due to gas molecules in the package. A package vacuum of less than 10 mTorr is maintained to reduce or eliminate the effect of gas thermal conduction in the package.

To maintain sub-10 m Torr package vacuum in a wafer-level vacuum package, uncooled FPA, getter material may be deposited on the interior surface of the window wafer within the vacuum package region. However, because the area of the silicon window wafer open to the scene aperture must be transparent to the incident scene radiation, the available area on the interior surface for getter deposition may be limited. In some embodiments of the disclosure, an enhanced getter area architecture is provided. The enhanced getter area architecture can use the presence of a cavity etched within the window to increase the getter area, thereby increasing getter sorption capacity.

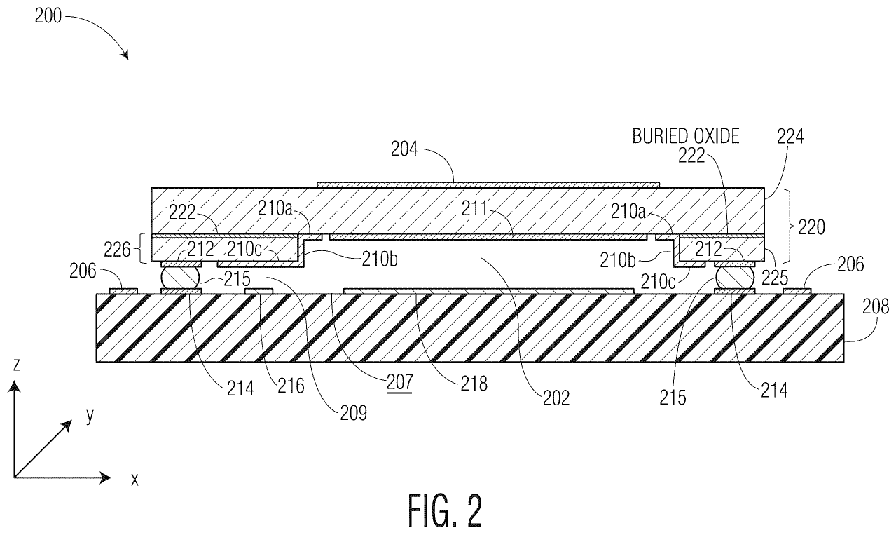

FIG. 2 is a cross-sectional view of a focal plane array (FPA) assembly according to an embodiment of the disclosure. The FPA assembly 200 can include a window die 220 and a device die 208. The window die 220 can be bonded to the device die 208 by solder joints 215. The device die 208 can include an infrared detector pixel array 218 disposed on a first surface 207 of the device die 208 and an optically blind infrared pixel array 216 disposed on the first surface 207. The device die 208 can further include solder ring metallizations 214. Solder joints 215 can be formed on the solder ring metallizations 214. The device die 208 may include bond pads 206 disposed on the first surface 207 of the device die 208. The bond pad 206 can be used for forming connections to a semiconductor package. The bond pad 206 can be used for forming connections to a semiconductor package, which interfaces with external camera electronics that drive the operation of the FPA assembly 200 and collect electrical output from the pixels in the FPA, which are used to for an infrared image of the scene.

The window die 220 can include a handle die 224 and a silicon on insulator die 226. In some embodiments, a thickness of the handle die 224 can be, for example, 600 μm, while a thickness of the silicon on insulator die 226 can be, for example, 200 μm. The silicon on insulator die 226 can include a single crystal silicon layer 225 disposed on a buried oxide layer 222. In some embodiments, a thickness of the buried oxide layer 222 can be, for example, 1 to 2 μm. The buried oxide layer 222 can be bonded to a bonding side surface of the handle die 224. The window die 220 can include a recess 202. The recess 202 may be formed by etching of the silicon on insulator die 226, where the etching also removes the buried oxide layer 222. The silicon on insulator die 226 may include solder ring metallizations 212. The solder joints 215 can be connected to the solder ring metallizations 212.

A cavity 209 can be formed adjacent the recess 202 and positioned between the device die 208 and the window die 220. The cavity 209 and the recess 202 can be vacuum environments. Getter material can be formed on a bonding side surface of the handle die 224 in regions 210a, on die wall surfaces in regions 210b, and on a second side surface of the silicon on insulator die 226 in regions 210c. In this way, getter material surface area can be increased or maximized within the cavity 209 and the recess 202 because the die wall surfaces are used to form getter material. The recess 202 can be made deeper or shallower by adjusting the thickness of the silicon on insulator die 226. Optical aperture permitting, the recess depth can be increased, thereby increasing available getter area on the die wall surfaces in regions 210b. In some embodiments, a perimeter of the recess 202, and thus the size of the recess 202, is reduced to enable formation of getter on all sides of the recess 202. In this way, the volume of the recess 202 is reduced while enabling additional getter material in the volume defined by the recess 202. Thus, embodiments of the present invention utilize the getter material to not only form an optical blocking structure above the infrared pixel array 216, but to also form an increased amount of getter material and an increased amount of getter area in the vacuum environment by depositing getter material both on die wall surfaces in region 210b and/or on the bonding side surface of the handle die 224 in regions 210a. It should be noted that embodiments of the present invention reduce the perimeter of recess 202 and, thereby, reduce the volume corresponding to the recess 202, which is typically undesirable since this reduction in volume reduces the volume to getter surface area ratio. However, since getter material is formed on die wall surfaces in region 210b, the volume to getter surface area ratio can be maintained or increased despite the reduced volume. As will be evident to one of skill in the art, the amount of getter material that can be formed on the bonding side surface of the handle die 224 in regions 210a is limited by the optical aperture that is needed to receive infrared radiation passing through the handle die 224 to the infrared detector pixel array 218. One of ordinary skill in the art would recognize many variations, modifications, and alternatives.

As illustrated in FIG. 2, the height of cavity 209, measured along the z-direction, can be much smaller than the height of recess 202, also measured along the z-direction. As discussed above, the height of recess 202 can be related to the thickness of the silicon on insulator die 226, for example, 200 μm, whereas, the height of cavity 209 can be related to the thickness of solder ring metallizations 212, solder joints 215, and solder ring metallizations 214, which can be on the order of 10 μm. Thus, blocking of light that would otherwise reach the infrared pixel array 216 is facilitated by embodiments of the present invention since positioning the getter material on regions 210c closer to the infrared pixel array 216 results in more effective light blocking performance. At the same time, the height of recess 202 is independent of the height of cavity 209, enabling a larger volume for a given surface area, which is desirable to achieve a low pressure (e.g., 10 mTorr) environment.

A first anti-reflection (AR) coating 204 may be formed on a planar side of the handle die 224. A second AR coating 211 may be formed on the bonding side surface of the handle die 224. The handle die 224 can be transparent to infrared radiation in order to enable infrared radiation to pass through the handle die 224 and impinge on the infrared detector pixel array 218. The AR coatings can be formed on both the planar and bonding sides of the handle die 224 in regions open to the collecting aperture for scene flux incident on the infrared detector pixel array 218. In some embodiments, the anti-reflection layer can be a deposited AR coating, for example, a multi-layer dielectric stack. In various embodiments, the AR layers can be formed from high spatial frequency, anti-reflection gratings etched into the handle die surfaces.

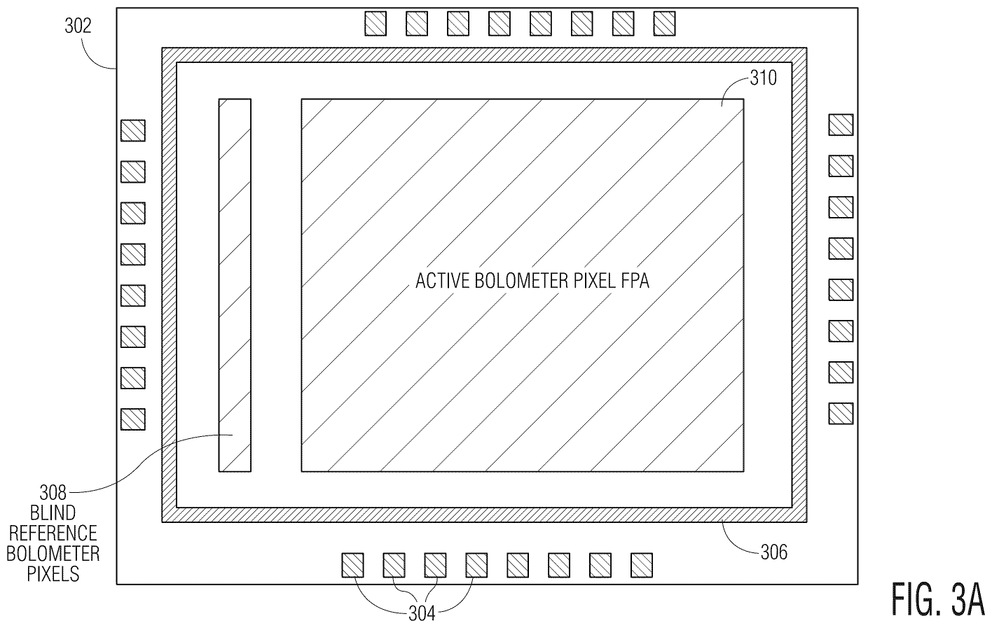

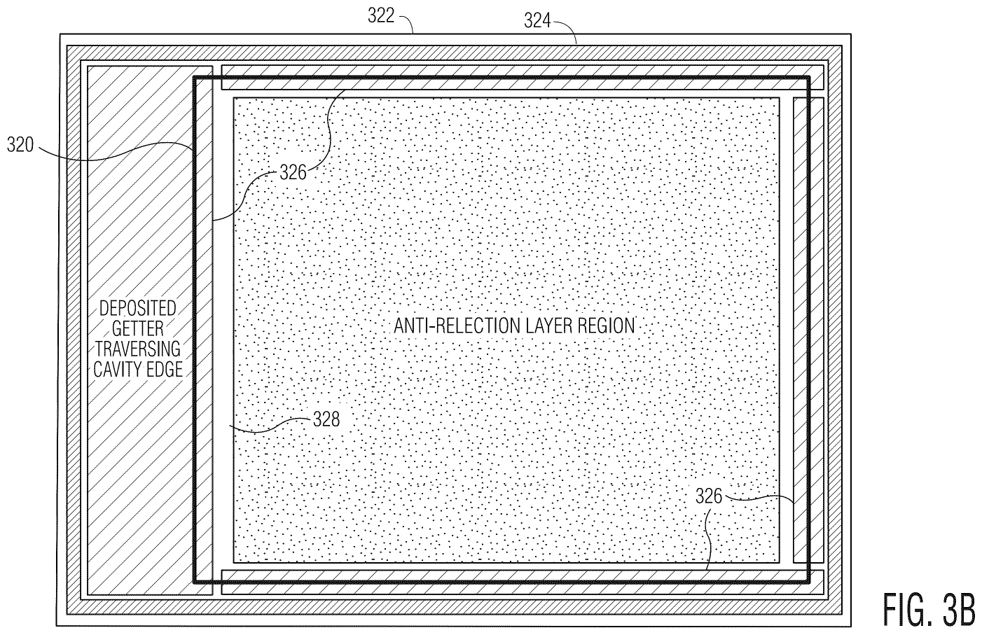

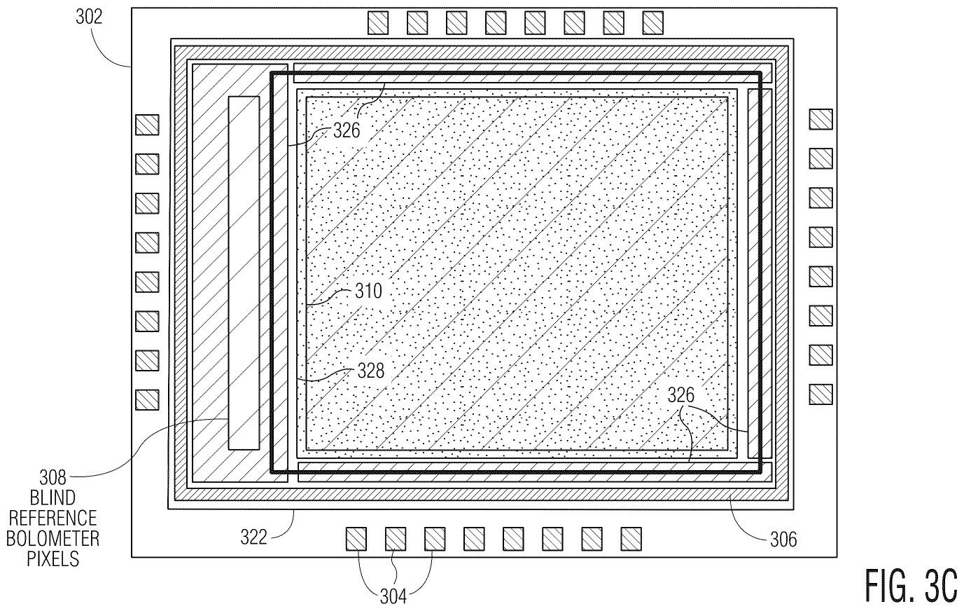

FIG. 3A shows a plan view of a device die with an infrared detector array and an infrared reference pixel array according to an embodiment of the disclosure. A device die 302 can include bond pads 304, solder ring metallization 306, an infrared pixel array 308, and an infrared detector pixel array 310, which can also be referred to as an array of blind reference bolometer pixels. As will be evident to one of skill in the art, the infrared pixel array 308, which includes detectors identical to the detectors in the infrared detector pixel array 310, will not be exposed to incident radiation and will provide a reference output (e.g., a resistance value) that can be utilized during calibration of the infrared detector pixel array 310 as well as during operation of the infrared detector pixel array 310.

FIG. 3B shows a plan view of a window die according to an embodiment of the disclosure. A window die 322 can include a solder ring metallization 324, a cavity edge 320, an AR layer region 328, and deposited getter regions 326.

FIG. 3C shows a plan view of bonded device die and window die of FIGS. 3A and 3B, respectively, according to an embodiment of the disclosure. The view in FIG. 3C is shown looking through the planar side of the handle die. The bonded device die 302, the window die 322, the bond pads 304, the solder ring metallization 306, the solder ring metallization 324, the infrared pixel array 308, the infrared detector pixel array 310, the AR layer region 328, and getter regions 326 are shown. In FIG. 3C, the solder ring metallization on the device die 302 is aligned to the corresponding solder ring metallization on the window die 322, thereby forming a hermetically sealed FPA package. FIG. 3C also shows a plan view of the getter regions 326, where the getter material is formed on the surface of the silicon on insulator die 226 at locations where the recess has not been formed, on the surface of the handle die in the recess region, and on die wall surfaces of the recess. FIG. 3C further shows the presence of the infrared pixel array 308, which can also be referred to as optically blind reference pixels, that are formed on the device die 302. As discussed previously, the present disclosure discloses a use of an enhanced area getter architecture to serve as a blocking structure optically upstream of the optically blind infrared pixel array 216. Although not illustrated in FIG. 3C because of the plan view that is illustrated, the getter material is formed on the die wall surfaces that extend into the plane of the figure in regions 210b at the cavity edge 320.

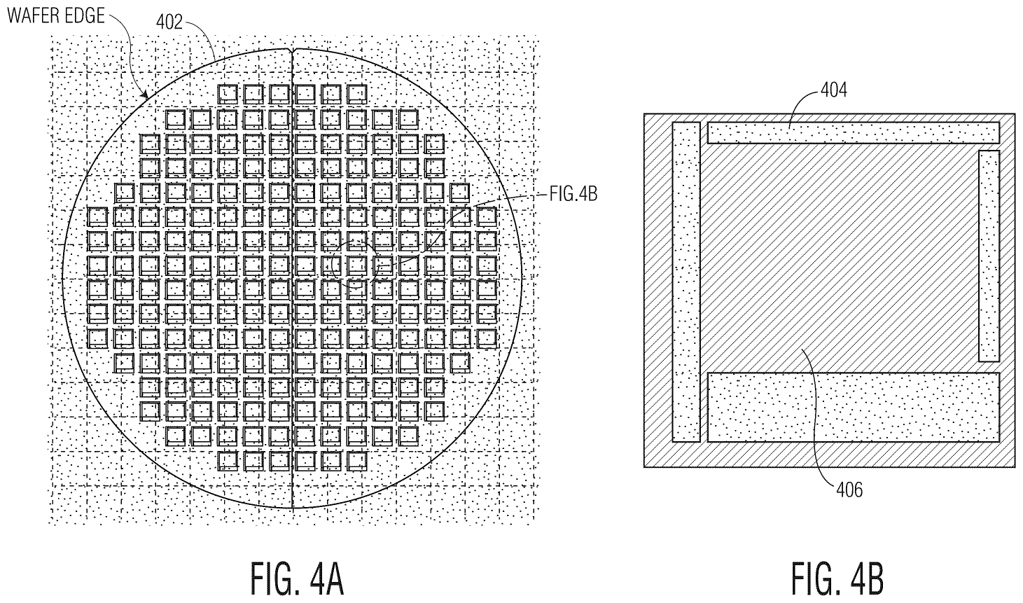

FIGS. 4A-B show plan views of a shadow mask used for deposition of getter material onto the focal plane array assembly of FIG. 2 according to an embodiment of the disclosure. FIG. 4A shows a plan view of a wafer shadow mask 402. FIG. 4B shows a close-up of a die level shadow mask having open regions 404 where there is no mask material, e.g., metal, present, and a shadowed region 406 where there is mask material, e.g., metal, present. Although some embodiments of the present invention are described in relation to the use of a shadow mask during getter deposition, other getter deposition processes are included within the scope of the present invention, including the use of photolithography and liftoff processes. One of ordinary skill in the art would recognize many variations, modifications, and alternatives.

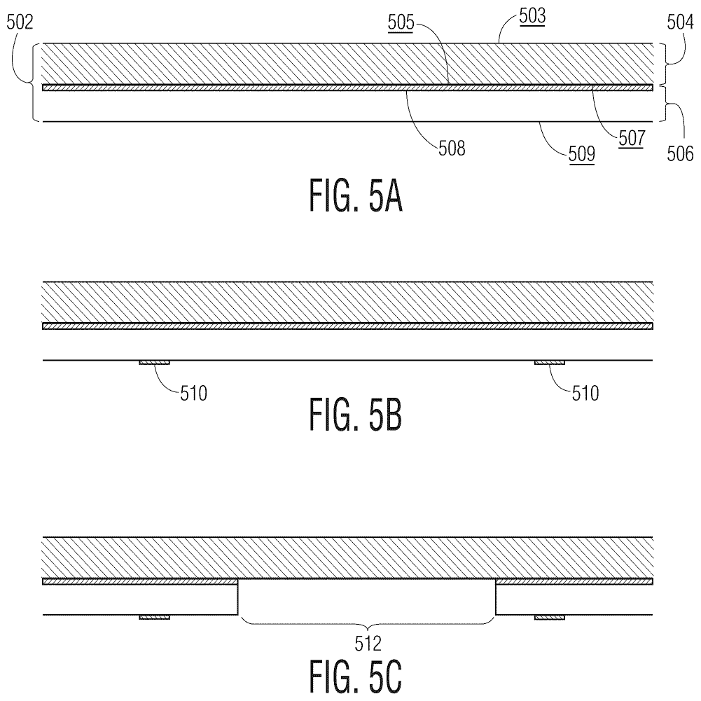

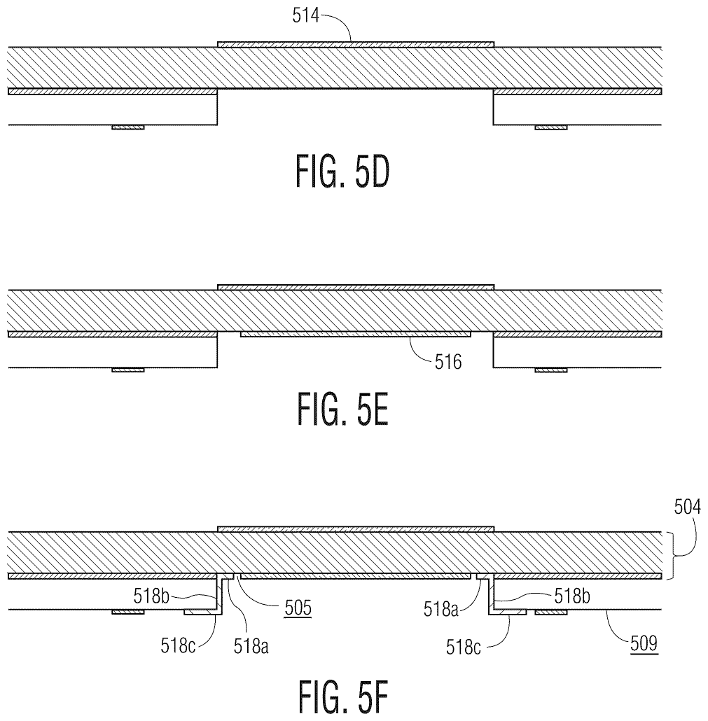

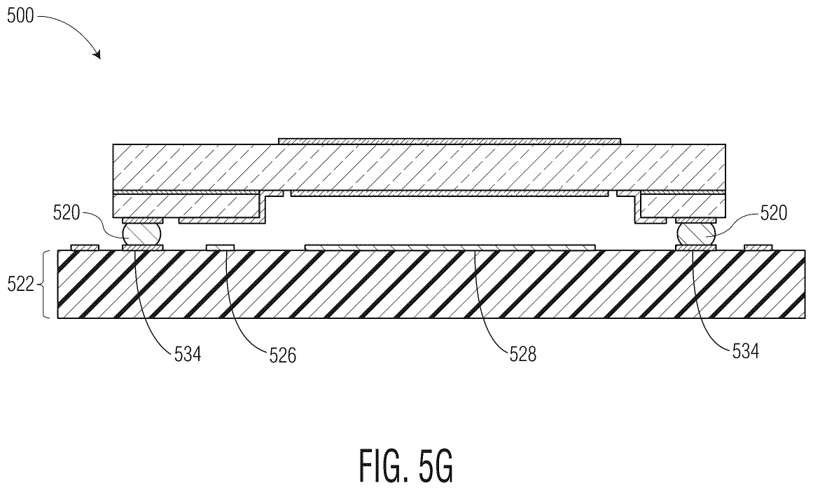

FIGS. 5A-5G are cross section views illustrating a method of fabricating a focal plane array assembly according to an embodiment of the disclosure. As shown in FIG. 5A, a handle wafer 504 and a silicon on insulator wafer 506 can be bonded to form a window wafer 502. The handle wafer can include a planar side 503 and a bonding side 505. The silicon on insulator wafer 506 can include a first side 507 and a second side 509, having a buried oxide layer 508 adjacent the first side 507. As shown in FIG. 5A, the first side 507 of the silicon on insulator wafer 506 is bonded to the bonding side 505 of the handle wafer 504.

FIG. 5B illustrates formation of solder ring metallizations 510 on the second side 509 of the silicon on insulator wafer 506. FIG. 5C illustrates formation of a recess 512 in the silicon on insulator wafer 506. The recess is formed by etching the recess 512 into the second side 509 of the silicon on insulator wafer 506. In some embodiments, the etching process is performed by dry etching followed by wet etching, where the buried oxide layer 508 is removed to expose a portion of the bonding side 505 of the handle wafer 504.

FIG. 5D illustrates formation of anti-reflection (AR) layer 514 on the planar side 503 of the handle wafer 504. FIG. 5E illustrates formation of AR layer 516 on the bonding side 505 of the handle wafer 504. The AR layers are formed in regions on both the planar side 503 and the bonding side 505 that are open and serve as a collection aperture for scene flux incident on the infrared detector pixel array 218 illustrated in FIG. 2. In some embodiments, the AR layer can be a coating, while in other embodiments the AR layer can be a high spatial frequency, anti-reflection grating etched into the planar side 503 and/or the bonding side 505 of the handle wafer 504.

FIG. 5F illustrates formation of getter regions on the bonding side 505 of the handle die wafer 504 in regions 518a, on die wall surfaces in regions 518b, and on the second side 509 of the silicon on insulator wafer 506 in regions 518c. As described previously, the getter is formed by evaporating getter material using a shadow mask. In some embodiments, the getter material can include, for example, but is not limited to, titanium or alloys of aluminum, zirconium, titanium, vanadium, and/or iron.

FIG. 5G illustrates formation of an FPA assembly by bonding a device wafer 522 to the window wafer 502 and singulating the FPA assembly 500. The device wafer 522 can include infrared detector pixel array 528, an optically blind infrared pixel array 526, and solder ring metallizations 534. The bonding of device wafer 522 to the window wafer 502 can be achieved by the formation of solder joint 520.

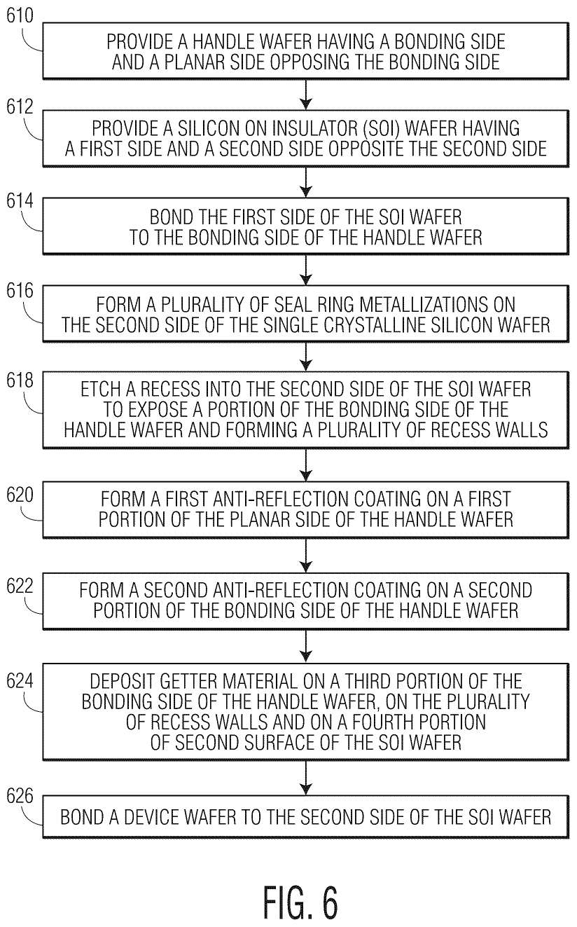

FIG. 6 illustrates a simplified flowchart illustrating a method of fabricating a focal plane array (FPA) assembly according to an embodiment of the disclosure. As illustrated in FIG. 6, the method of fabricating the FPA assembly includes providing a handle wafer having a bonding side and a planar side opposing the bonding side (610). The method also includes providing a silicon on insulator wafer having a first side and a second side opposite the second side (612). The method further includes bonding the first side of the silicon on insulator wafer to the bonding side of the handle wafer (614).

Additionally, the method includes forming a plurality of seal ring metallizations on the second side of the silicon on insulator wafer (616). The method further includes etching a recess into the second side of the silicon on insulator wafer to expose a portion of the bonding side of the handle wafer and forming a plurality of recess walls (618). Further, the method includes forming a first anti-reflection (AR) coating on a first portion of the planar side of the handle wafer (620). Moreover, the method includes forming a second AR coating on a second portion of the bonding side of the handle wafer (622). In some embodiments, the second AR coating is optional, for example, in a low cost implementation in which the cavity side AR coating is eliminated and an even lower cost implementation in which both the planar and cavity side AR coatings are eliminated. Additionally, the method includes depositing getter material on a third portion of the bonding side of the handle wafer, on the plurality of recess walls, and on a fourth portion of second side of the silicon on insulator wafer (624) and bonding a device wafer to the silicon on insulator wafer (626), for example, to the second side of the silicon on insulator wafer.

It should be appreciated that the specific steps illustrated in FIG. 6 provide a particular method of fabricating an FPA assembly according to an embodiment of the disclosure. Other sequences of steps may also be performed according to alternative embodiments. For example, alternative embodiments of the disclosure may perform the steps outlined above in a different order. Moreover, the individual steps illustrated in FIG. 6 may include multiple sub-steps that may be performed in various sequences as appropriate to the individual step. Furthermore, additional steps may be added or removed depending on the particular applications. One of ordinary skill in the art would recognize many variations, modifications, and alternatives.

Various examples of the present disclosure are provided below. As used below, any reference to a series of examples is to be understood as a reference to each of those examples disjunctively (e.g., “Examples 1-4” is to be understood as “Examples 1, 2, 3, or 4”).

Example 1 is a focal plane array (FPA) assembly comprising: a device die having a first device surface, an infrared detector array disposed on the first device surface, and an infrared reference pixel array disposed on the first device surface; a window die bonded to the device die, wherein the window die includes a recess and comprises: a first die surface that overlies the infrared detector array; a second die surface that overlies the infrared reference pixel array; and a die wall surface joining the first die surface and the second die surface, wherein the die wall surface forms a perimeter of the recess; and a getter material disposed on at least one of the die wall surface or the first die surface.

Example 2 is the FPA assembly of example 1, wherein the recess extends into the window die along a first direction and the first die surface overlaps the infrared detector array in a plane orthogonal to the first direction.

Example 3 is the FPA assembly of example(s) 1-2, wherein the getter material is disposed on a portion of the second die surface.

Example 4 is the FPA assembly of example(s) 1-3, wherein the second die surface overlaps the infrared reference pixel array in the plane orthogonal to the first direction.

Example 5 is the FPA assembly of example 1, wherein the perimeter of the recess is defined by four die wall surfaces and the getter material is disposed on the four die wall surfaces.

Example 6 is the FPA assembly of example 1, further comprising a seal ring disposed between the device die and the window die and encircling the recess.

Example 7 is the FPA assembly of example(s) 1 and 6, wherein the window die, the device die, and the seal ring form a hermetic cavity overlapping the infrared detector array.

Example 8 is the FPA assembly of example(s) 1 and 6, wherein the seal ring comprises solder ring metallization and solder joints.

Example 9 is the FPA assembly of example 1, wherein the infrared reference pixel array is disposed outside of the perimeter of the recess.

Example 10 is the FPA assembly of example 1, wherein the getter material comprises titanium.

Example 11 is the FPA assembly of example 1, wherein the getter material is non-optically transmissive.

Example 12 is the FPA assembly of example 1, wherein the getter material forms an optical blocking structure for the infrared reference pixel array.

Example 13 is the FPA assembly of example 1, wherein pixel elements of the infrared reference pixel array are identical in configuration to pixel elements of the infrared detector array.

Example 14 is the FPA assembly of example 1, wherein a pixel element of the infrared detector array comprises a microbolometer detector pixel element.

Example 15 is a method of fabricating a focal plane array (FPA) assembly, the method comprising: providing a handle wafer having a bonding side and a planar side opposing the bonding side; providing a silicon on insulator wafer having a first side and a second side opposite the first side; providing a device wafer having a plurality of solder joints; bonding the first side of the silicon on insulator wafer to the bonding side of the handle wafer; forming a plurality of seal ring metallizations on the second side of the silicon on insulator wafer; etching a recess into the second side of the silicon on insulator wafer to expose a portion of the bonding side of the handle wafer and forming a plurality of recess walls; forming a first anti-reflection coating on a first portion of the planar side of the handle wafer; forming a second anti-reflection coating on a second portion of the bonding side of the handle wafer; depositing getter material on a third portion of the bonding side of the handle wafer, on the plurality of recess walls and on a fourth portion of the second side of the silicon on insulator wafer; and bonding the device wafer to the second side of the silicon on insulator wafer.

Example 16 is the method of fabricating the FPA assembly of example 15, wherein the etching the recess into the second side of the silicon on insulator wafer is performed by dry etching followed by wet etching.

Example 17 is the method of fabricating the FPA assembly of example 15, wherein the device wafer comprises an infrared detector pixel array and an infrared reference pixel.

Example 18 is the method of fabricating the FPA assembly of example(s) 15 and 17, wherein the infrared reference pixel is identical in configuration to a pixel element of the infrared detector pixel array.

Example 19 is the method of fabricating the FPA assembly of example 15, wherein depositing getter material is performed using a shadow mask.

Example 20 is the method of fabricating the FPA assembly of example 15, wherein the first portion of the bonding side of the handle wafer is disposed inside the plurality of recess walls.

Example 21 is the method of fabricating the FPA assembly of example 15, wherein the fourth portion of the second side of the silicon on insulator wafer is disposed outside the plurality of recess walls.

Example 22 is the method of fabricating the FPA assembly of example 15, wherein bonding the device wafer to the silicon on insulator wafer is performed by attaching the plurality of solder joints to the plurality of seal ring metallizations on the second side of the silicon on insulator wafer.

Example 23 is the method of fabricating the FPA assembly of example 15, wherein depositing getter material is performed after forming the first anti-reflection coating.

One of ordinary skill in the art will appreciate that other modifications to the apparatuses and methods of the present disclosure may be made for implementing various applications of the methods and systems for enhanced area getter architecture for a wafer-level vacuum packaged uncooled focal plane array without departing from the scope of the present disclosure.

The examples and embodiments described herein are for illustrative purposes only. Various modifications or changes in light thereof will be apparent to persons skilled in the art. These are to be included within the spirit and purview of this application, and the scope of the appended claims which follow.

What is claimed is:

1. A focal plane array (FPA) assembly comprising:
a device die having a first device surface, an infrared detector array disposed on the first device surface, and an infrared reference pixel array disposed on the first device surface;
a window die bonded to the device die, wherein the window die includes a recess and comprises:
a first die surface that overlies the infrared detector array;
a second die surface that overlies the infrared reference pixel array; and
a die wall surface joining the first die surface and the second die surface, wherein the die wall surface forms a perimeter of the recess; and
a getter material disposed on at least one of the die wall surface or the first die surface.

2. The FPA assembly of claim 1, wherein the recess extends into the window die along a first direction and the first die surface overlaps the infrared detector array in a plane orthogonal to the first direction.

3. The FPA assembly of claim 2, wherein the getter material is disposed on a portion of the second die surface.

4. The FPA assembly of claim 3, wherein the second die surface overlaps the infrared reference pixel array in the plane orthogonal to the first direction.

5. The FPA assembly of claim 1, wherein the perimeter of the recess is defined by four die wall surfaces and the getter material is disposed on the four die wall surfaces.

6. The FPA assembly of claim 1, further comprising a seal ring disposed between the device die and the window die and encircling the recess.

7. The FPA assembly of claim 6, wherein the window die, the device die, and the seal ring form a hermetic cavity overlapping the infrared detector array.

8. The FPA assembly of claim 6, wherein the seal ring comprises solder ring metallization and solder joints.

9. The FPA assembly of claim 1, wherein the infrared reference pixel array is disposed outside of the perimeter of the recess.

10. The FPA assembly of claim 1, wherein the getter material comprises titanium.

11. The FPA assembly of claim 1, wherein the getter material is non-optically transmissive.

12. The FPA assembly of claim 1, wherein the getter material forms an optical blocking structure for the infrared reference pixel array.

13. The FPA assembly of claim 1, wherein pixel elements of the infrared reference pixel array are identical in configuration to pixel elements of the infrared detector array.

14. The FPA assembly of claim 1, wherein a pixel element of the infrared detector array comprises a microbolometer detector pixel element.

15. A method of fabricating a focal plane array (FPA) assembly, the method comprising:
providing a handle wafer having a bonding side and a planar side opposing the bonding side;
providing a silicon on insulator wafer having a first side and a second side opposite the first side;
providing a device wafer having a plurality of solder joints;
bonding the first side of the silicon on insulator wafer to the bonding side of the handle wafer;
forming a plurality of seal ring metallizations on the second side of the silicon on insulator wafer;
etching a recess into the second side of the silicon on insulator wafer to expose a portion of the bonding side of the handle wafer and forming a plurality of recess walls;
forming a first anti-reflection coating on a first portion of the planar side of the handle wafer;
forming a second anti-reflection coating on a second portion of the bonding side of the handle wafer;
depositing getter material on a third portion of the bonding side of the handle wafer, on the plurality of recess walls and on a fourth portion of the second side of the silicon on insulator wafer; and
bonding the device wafer to the second side of the silicon on insulator wafer.

16. The method of claim 15, wherein the etching the recess into the second side of the silicon on insulator wafer is performed by dry etching followed by wet etching.

17. The method of claim 15, wherein the device wafer comprises an infrared detector pixel array and an infrared reference pixel.

18. The method of claim 17, wherein the infrared reference pixel is identical in configuration to a pixel element of the infrared detector pixel array.

19. The method of claim 15, wherein depositing getter material is performed using a shadow mask.

20. The method of claim 15, wherein the first portion of the bonding side of the handle wafer is disposed inside the plurality of recess walls.
